(19) United States
(12) Patent Application Publication
(10) Pub. No.: US 2015/0354753 A1
(43) Pub. Date: Dec. 10, 2015

(54) Adjustable Hands-Free Media Holding Device

(71) Applicant: Tina Courtwright, Minoa, NY (US)

(72) Inventor: Tina Courtwright, Minoa, NY (US)

(21) Appl. No.: 14/731,746

(22) Filed: Jun. 5, 2015

Related U.S. Application Data
(60) Provisional application No. 62/008,668, filed on Jun. 6, 2014.

(51) Int. Cl. F16M 13/04; H05K 5/00; H05K 5/02; A44B 18/00

(52) U.S. Cl. CPC F16M 13/04; A44B 18/0069; H05K 5/0086; H05K 5/0204

(57) ABSTRACT

An adjustable hands-free media holding device for use in holding media of various sizes and configurations in front of the user. The media holding device includes a platform having a planar surface and further includes a neck strap having a first end secured to a first side of the platform and having a second end secured to a second side of the platform. The platform can be used to support media and includes a curved lower end that rests flush against the user's chest. In an alternative embodiment, the platform includes an upper section adjustably secured to a lower section, wherein the platform can fold into a compact configuration or angle towards a user's face. The media holding device further includes one or more fasteners, such as hook and loop material, attached to the surface thereof, wherein a ledge is removably attached thereto so as to support media thereon.

### CROSS REFERENCE TO RELATED APPLICATION

This application claims the benefit of U.S. Provisional Application No. 62/008,668 filed on Jun. 6, 2014. The above identified patent application is herein incorporated by reference in its entirety to provide continuity of disclosure.

### BACKGROUND OF THE INVENTION

### Field of the Invention

The present invention relates to an adjustable hands-free media holding device. More specifically, the present invention provides a device comprising a platform having a neck strap attached thereto, wherein the platform further includes a ledge removably secured thereon and is adapted to hold media, such as a book or tablet. The lower end of the platform can be positioned flush against a user's chest, and the neck strap can be placed around the neck to support the device on the user's body, eliminating the need for the user to hold the media in his or her hands.

When reading from a tablet or an e-reader, individuals generally hold the media in front of them with both arms extended to the desired distance. It can be extremely tiring to hold electronic or non-electronic media devices aloft for extended periods of time, which can make the reading or viewing process unenjoyable or lead to back and neck aches. Furthermore, there exists media of varying sizes and configurations, such as books, cellular phones, tablets, mini-tablets, and other e-readers. A hands-free carrying device that can only hold a tablet or book of one size and configuration is of limited use. Therefore, there is a need in the prior art for a device that is adapted to hold media in a manner that adjusts to the size and configuration of such media, allowing the user to have a comfortable reading or viewing position while simultaneously having hands-free functionality.

Devices have been disclosed in the prior art that relate to hands-free media holders. These include devices that have been patented and published in patent application publications. These devices generally relate to supporting portable media, such as a laptop computer, on a stand comprising a strap secured to the human body. Such devices include U.S. Pat. No. 5,667,114 to Bourque, U.S. Publication Number 2003/0201295 to Beatto, and U.S. Publication Number 2013/0187024 to Obujen et al. These devices, however, fail to provide an adjustable ledge or similar feature that enables the user to account for the size and the configuration of the media. Furthermore, such devices fail to provide a platform having a curved lower end that allows the device to rest flush against a user's chest.

Other devices in the prior art disclose devices used to carry electronics on a pivoting stand, which can be connected to the human body, such as, U.S. Publication Number 2012/0068044 to Rivera and U.S. Publication Number 2011/0315733 to White. Again, these devices do not provide means for adjustably supporting tablets and other media. Additionally, such devices lack a curved lower end that allows the device to rest flush against the user's body.

In light of the devices disclosed in the prior art, it is submitted that the present invention substantially diverges in design elements from the prior art and consequently it is clear that there is a need in the art for an improvement to existing hands-free media holding devices. In this regard the instant invention substantially fulfills these needs.

### SUMMARY OF THE INVENTION

In view of the foregoing disadvantages inherent in the known types of hands-free media holding devices now present in the prior art, the present invention provides a new adjustable hands-free media holding device wherein the same can be utilized for providing convenience for the user when carrying and viewing media while hands-free.

It is therefore an object of the present invention to provide a new and improved adjustable hands-free media holding device that has all of the advantages of the prior art and none of the disadvantages.

It is another object of the present invention to provide an adjustable hands-free media holding device comprising a platform for supporting a tablet or other media thereon, wherein the platform includes one or more neck straps secured thereto, and wherein the device further includes an adjustable ledge disposed on the platform.

Another object of the present invention is to provide an adjustable hands-free media holding device having a platform with a curved lower end adapted to rest flush against a human chest.

Yet another object of the present invention is to provide an adjustable hands-free media holding device having a ledge containing hook material disposed on the lower end of the ledge so that the ledge can be removably secured to loop material disposed on the platform.

Yet another object of the present invention is to provide an adjustable hands-free media holding device wherein, in an alternative embodiment, the platform comprises an upper section adjustably secured to a lower section by one or more fasteners adapted to allow the platform to fold into a compact configuration or the upper section to angle towards a user's face.

Another object of the present invention is to provide an adjustable hands-free media holding device that may be readily fabricated from materials that permit relative economy and are commensurate with durability.

Other objects, features and advantages of the present invention will become apparent from the following detailed description taken in conjunction with the accompanying drawings.

### BRIEF DESCRIPTIONS OF THE DRAWINGS

Although the characteristic features of this invention will be particularly pointed out in the claims, the invention itself and manner in which it may be made and used may be better understood after a review of the following description, taken in connection with the accompanying drawings wherein like numeral annotations are provided throughout.

FIG. 1 shows a side perspective view of an embodiment of the media holding device.

FIG. 2 shows a top down view of the platform of the media holding device.

FIG. 3A shows a perspective view of the ledge of the media holding device.

FIG. 3B shows a perspective view of the stylus holder of the media holding device.

FIG. 4 shows a perspective view of an alternative embodiment of the platform of the media holding device.

FIG. 5A shows a side perspective view of an embodiment of the media holding device in use with a small electronic device.

FIG. 5B shows a side perspective view of an embodiment of the media holding device in use with a larger electronic device, further illustrating the adjustability of the invention.

### DETAILED DESCRIPTION OF THE INVENTION

Reference is made herein to the attached drawings. Like reference numerals are used throughout the drawings to depict like or similar elements of the adjustable hands-free media holding device. For the purposes of presenting a brief and clear description of the present invention, the preferred embodiment will be discussed as used for supporting a tablet or other media for viewing by the user, wherein the user can retain full use of his or her hands. The figures are intended for representative purposes only and should not be considered to be limiting in any respect.

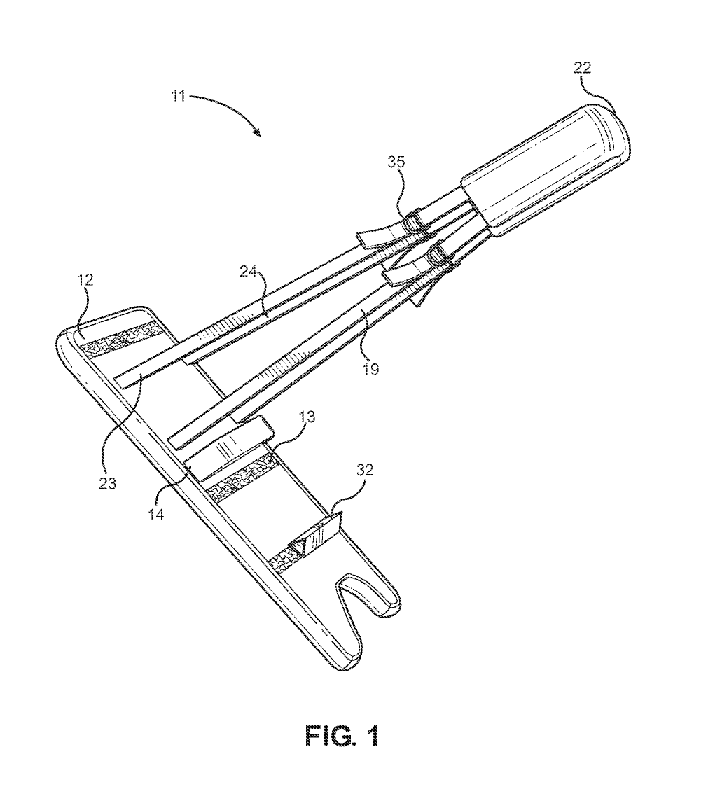

Referring now to FIG. 1, there is shown a side perspective view of an embodiment of the adjustable hands-free media holding device. The media holding device 11 comprises a platform 12 having a planar surface and one or more neck straps 19 attached thereto. The neck straps 19 can be disposed around the user's neck so as to support and position the platform 12 in front of the user's body. The user can then place media, such as a tablet or book, flush against the surface of the platform 12. The media holding device 11 further includes one or more strips of loop material 13 horizontally extending from one side of the surface of the platform 12 to the opposing side, wherein an elongated ledge 14 is removably attached to the strips 13. The ledge 14 serves to position the media in a desired location on the platform 12 for ease of viewing the media, and helps to prevent the media from sliding or moving on the platform 12. The device 11 further includes a holder 32 for a stylus, wherein the holder 32 is removably attached to a strip of loop material 13. The holder allows convenient access to a stylus adapted to be used with the media device removably secured on the platform 12.

One or more neck straps 19 are secured to the platform 12. The neck strap 19 comprises a first end 23 and a second end 24, wherein the first end 23 is connected to the first side of the platform 20 and the second end 24 is connected to the second side of the platform 21. Each neck strap 19 is connected to the platform 12 by any suitable fastener, such as screws, bolts, glue, or adhesives, among others. The neck strap 19 is flexible and can be composed of plastic, elastic material, or fabric. The neck strap 19 can rest against the back of the user's neck and may include a cushion 22 thereon for providing comfort to the user. The cushion 22 is connected to the neck strap 19 by any suitable fastener, such as an adhesive or stitching, and is disposed centrally on the neck strap 19 so to support the user's neck. The neck strap 19 is adjustable in length and includes an adjustment mechanism 35, such as a buckle, for allowing a user to selectively elongate the neck strap 19.

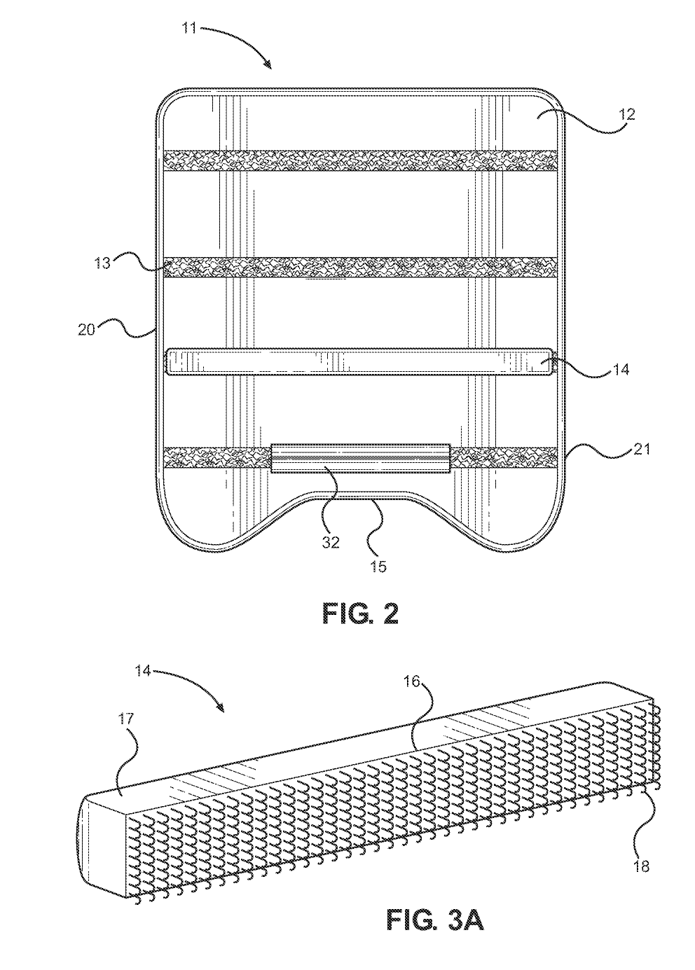

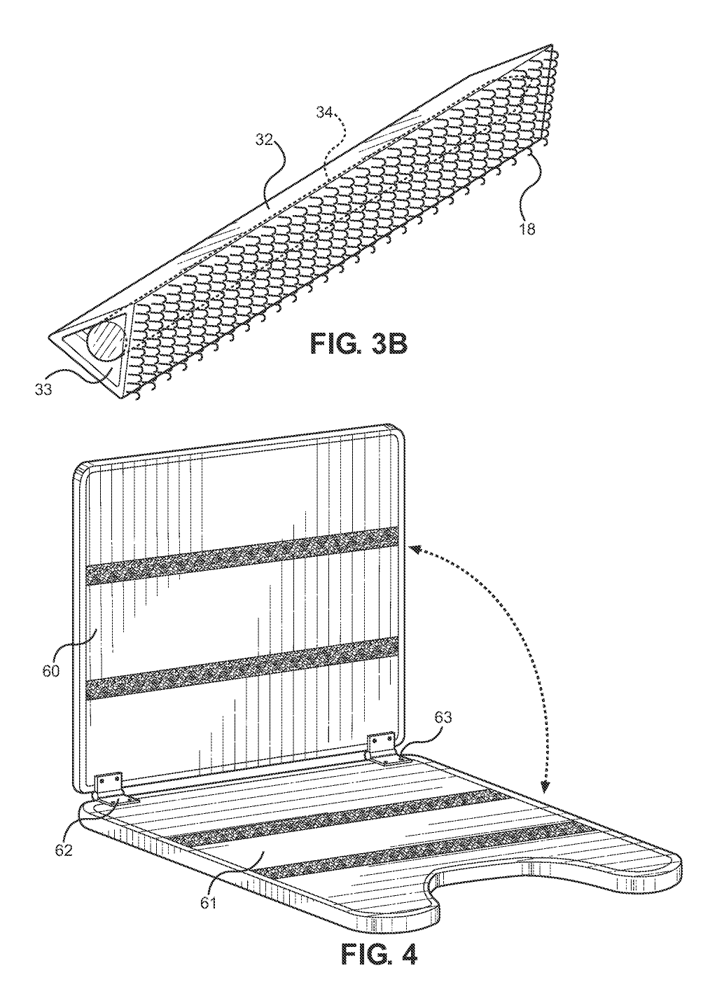

Referring now to FIGS. 2, 3A, and 3B, there is shown a top down view of the platform of the media holding device, and perspective views of the ledge and holder of the media holding device. The media holding device 11 comprises a platform 12 with an upper end, a lower end 15, and a first side 20 opposite a second side 21. The platform 12 is preferably substantially rectangular in configuration. The upper surface of the platform 12 is substantially planar so that a tablet, smartphone or other device can be rested flush thereon. The lower end 15 of the platform 12 is curved so to aid in positioning the platform 12 on the user's body and so as to allow the platform 12 to rest flush against a user's body. The lower end 15 is concave and the curve extends between the first side 20 and the second side 21 of the platform 12. The curved lower end 15 can rest against a user's chest, abdomen, or any other location on the front of a user's body.

One or more strips of loop material 13 are disposed on the platform 12, and arranged in a row along the first side 20 and along the second side 21 of the platform 12. Preferably, the strips 13 extend horizontally from the first side 20 to the second side 21 of the platform 12. The strips 13 are preferably spaced at a fixed interval. The ledge 14 of the present invention can be supported on a strip 13, wherein the ledge 14 aligns with the strip 13 and is placed on the platform 12. Thus, the strips 13 are provided so as to allow the ledge 14 to be secured to the platform 12 at various positions thereon. The strips 13 are elongated and rectangular in configuration, but may be shaped in any manner congruent to the shape of the shape of the lower end 16 of the ledge 14. The dimension of the strip 13 is no larger than the dimension of the lower end 16 of the ledge 14.

The ledge 14 preferably comprises an elongated rectangular bar having an upper end 17 and a lower end 16. The ledge 14 is adapted to support the lower end of a tablet or other media so that the media does not slide downward on the platform 12. The ledge 14 can be removably disposed in a horizontal orientation on the platform 12 so that it extends between the first side 20 and second side 21, and so that it is parallel to the upper end of the platform 12. Preferably, the ledge 14 is linear so it can evenly support the weight of the tablet. However, in alternate embodiments the ledge 14 can have other configurations suitable for supporting the lower end of a tablet so that the tablet is maintained in a level position of the platform 12. The lower end 16 of the ledge 14 includes an elongated strip of hook material 18. The strip of hook material 18 removably secures to the corresponding strip of loop material 13 disposed on the surface of the platform 12. The strip of hook material 18 disposed on the lower end 16 of the ledge 14 can engage with a strip of loop material 13 on the platform 12 so as to secure the ledge 14 to the platform 12 in the desired position.

The device 11 further includes a holder 32 adapted to hold a stylus 34 therein. The holder 32 comprises a base, one or more sidewalls, and an open upper end 33. The stylus can be placed in the holder 32 through the open end 33. The holder 32 is elongated and triangular in configuration. However, in alternate embodiments the holder 32 can have other configurations suitable for holding a stylus 34 therein. The holder 32 further includes a strip of hook material 18 disposed on the surface of a sidewall adapted to be placed onto a strip of loop material 13 disposed on the platform 12. In this way, the holder provides convenient access to a stylus 34 adapted to be used with the media device removably secured on the platform 12.

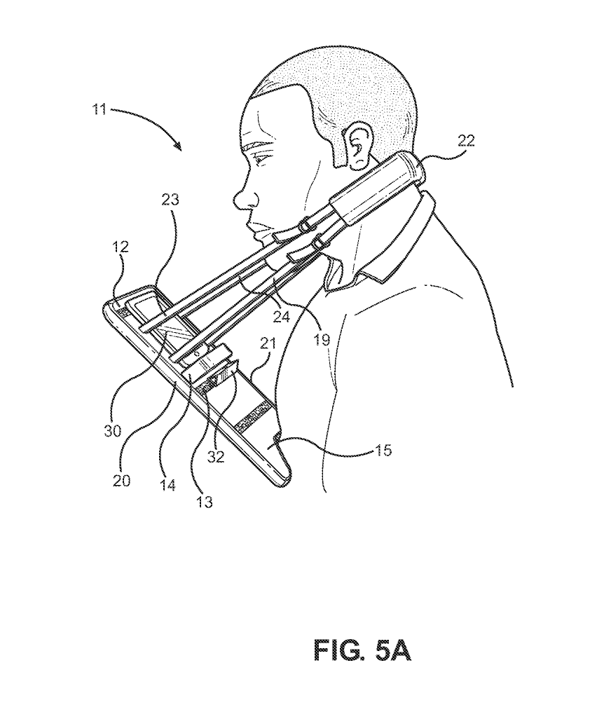

Referring now to FIG. 4, there is shown an alternative embodiment of the platform of the media holding device. In an alternative embodiment, the platform comprises an upper section 60 and a lower section 61, wherein the upper section 60 is adjustably secured to the lower section 61 by one or more fasteners 62, such as a locking hinge 63. The locking hinge 63 is adapted to remain in a static position at various angles. In operation, the locking hinge 63 allows the platform to fold into a compact configuration for storage or adjustably secure the platform in a tilted position so that the upper section 61 of the platform 12 is directed towards the user's face. In this way, the platform is adapted to provide the user with various viewing angles of media placed thereon.

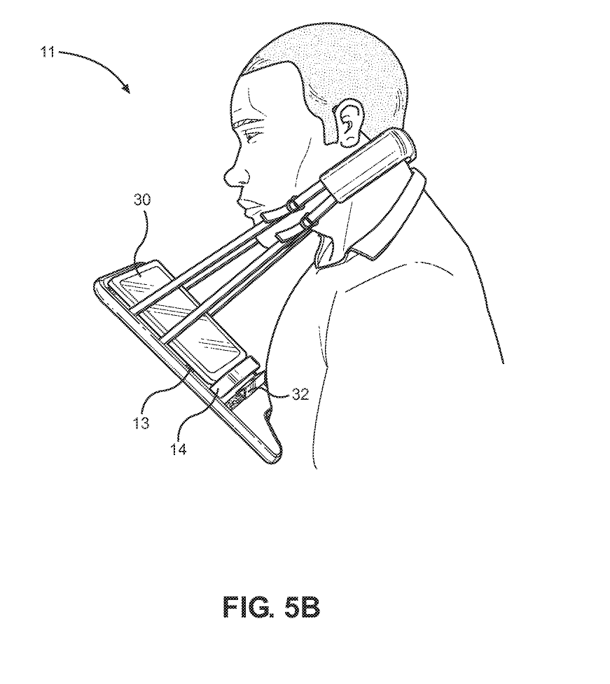

Referring now to FIGS. 5A and 5B, there are shown side perspective views of the adjustable hands-free media holding device 11 in use. In operation, a user can first dispose the neck strap 19 around his or her neck. One or more neck straps 19 may be adjusted to a particular length so the lower end 15 of the platform 12 can rest flush against the user's chest and may be tilted to the preferred angle of the user. The platform 12 is preferably tilted at an upward angle relative to a horizontal plane so that the platform 12 is directed towards the user's face. Once the platform 12 and neck strap 19 are in a desired position, the user can secure the elongated ledge 14 on the platform 12 by engaging the hook material disposed on the lower end of the ledge 14 with a strip of loop material 13 disposed vertically on the surface of the platform 12. The user can move the ledge 14 onto various strips 13 depending upon the size of the media and depending upon the user's desired viewing position. Once the ledge 14 is in position, the user can place the lower end of a tablet 30 or other media onto the upper end of the ledge 14, resting the backside of the tablet flush against the surface of the platform 12. In this way, the tablet 30 is supported by the platform 12 in a suitable position for viewing while the user remains hands-free. In some embodiments, the device 11 includes an additional strip of hook material adapted to be placed on the backside of a tablet or other media. In this way, the strip of hook material included on the tablet can align with and be positioned on a strip of loop material 13 disposed on the platform 12, thereby providing further stability so as to allow the tablet to remain in position on the platform 12.

In an alternate embodiment, the media holding device includes a ledge movably positioned on the platform via a sliding mechanism. In such embodiments, the platform includes an elongated channel on the first and second sides thereof extending from the lower end to the upper end of the platform. The ledge includes one or more protrusions that are engaged with the channels on the platform. The protrusions can slide within the channels so that the user can adjust the ledge to the desired position on the platform. The platform may further include a locking mechanism so as to secure the ledge in a desired position, and so as to prevent the ledge from sliding on the platform when a tablet or other media is placed thereon.

It is therefore submitted that the instant invention has been shown and described in what is considered to be the most practical and preferred embodiments. It is recognized, however, that departures may be made within the scope of the invention and that obvious modifications will occur to a person skilled in the art. With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

Therefore, the foregoing is considered as illustrative only of the principles of the invention. Further, since numerous modifications and changes will readily occur to those skilled in the art, it is not desired to limit the invention to the exact construction and operation shown and described, and accordingly, all suitable modifications and equivalents may be resorted to, falling within the scope of the invention.

I claim:

1. An adjustable hands-free media holding device, comprising:
a platform having a first side opposite a second side;
a ledge having an upper end and a lower end, wherein said ledge is movable on said platform;
one or more straps each having a first end and a second end, wherein said first end is connected to said first side of said platform and said second end is connected to said second side of said platform, wherein said one or more straps are adapted to be disposed around the neck of a user.

2. The adjustable hands-free media holding device of claim 1, wherein said platform is substantially rectangular in configuration.

3. The adjustable hands-free media holding device of claim 1, wherein said planar platform comprises a lower end that is curved such that said platform is adapted to rest flush against a human chest.

4. The adjustable hands-free media holding device of claim 1, wherein said ledge is removably secured to said platform and is adapted to engage with one or more strips of loop material extending from said first side of said platform to said second side of said platform.

5. The adjustable hands-free media holding device of claim 4, wherein the ledge includes a strip of hook material adapted to receive said one or more strips of loop material thereon for securing said ledge to said platform.

6. The adjustable hands-free media holding device of claim 4, wherein said one or more strips of loop material are spaced at a fixed interval.

7. The adjustable hands-free media holding device of claim 4, wherein said one or more strips of loop material are arranged horizontally on said platform.

8. The adjustable hands-free media holding device of claim 1, further comprising a cushion positioned on said one or more neck straps.

9. The adjustable hands-free media holding device of claim 1, wherein said one or more neck straps are adjustable in length.

10. The adjustable hands-free media holding device of claim 1, further comprising a holder removably secured to said platform, wherein said holder comprises a base, one or more sidewalls, and an open upper end adapted to hold a stylus therein.

11. The adjustable hands-free media holding device of claim 1, wherein said platform comprises an upper section and a lower section, wherein said upper section and said lower section are adjustably secured by one or more fasteners.

12. The adjustable hands-free media holding device of claim 11, wherein said fastener is a locking hinge.
